(19) United States
(12) Patent Application Publication
(10) Pub. No.: US 2005/0042852 A1
(43) Pub. Date: Feb. 24, 2005

(54) Method for applying solder mask onto pad spacings of a printed circuit board

(75) Inventors: Cheng-Hsien Chou, Taipei County (TW); Hung-Yi Yeh, Taipei County (TW); Smoon Lin, Taipei County (TW)

Correspondence Address: BACON & THOMAS, PLLC, 625 SLATERS LANE, FOURTH FLOOR, ALEXANDRIA, VA, 22314, US

(73) Assignee: Unitech Printed Circuit Board Corp., Taipei (TW)

(21) Appl. No.: 10/642,609

(22) Filed: Aug. 19, 2003

(51) Int. Cl. H01L 21/44

(52) U.S. Cl. 438/612

(57) ABSTRACT

A method for applying the solder mask onto solder pad spacings of a printed circuit board, mainly referring to the use of an ink-jet printer for printing the solder mask at the dense solder pad area on a printed circuit board, so as to prevent the solder mask from being coated onto solder pads in the dense solder pad area, thus improving the reliability of assembling processes for electronic products, and further providing merits of minimizing clearances between the solder mask and solder pads and increasing the adhesion of the solder mask.

### BACKGROUND OF THE INVENTION

1. Field of the Invention

The present invention relates to a method for applying the solder mask onto solder pad spacings, more particularly, a method of using an ink-jet printer to print the solder mask to solder pad spacings in the dense solder pad area on a printed circuit board (“PCB”).

2. Description of the Related Art

As shown in FIG. 4 and the left portion of Line A in FIG. 5, the conventional technology of producing the solder mask 30 on a PCB 20 is to print the solder mask on overall PCB surface, then use the negative film to transfer image by UV light exposure (Negative-film exposure process), and then develop and bake the solder mask, thus the solder mask coats over the PCB surface except the solder pads 22 during the assembly of electronic parts. The solder mask 30 formed between two solder pads 22 is also called solder dam, which is for preventing from the formation between two solder pads 22 of a solder bridge that causes short circuitry. In other words, the left portion of Line A in FIG. 5 shows the ideal state of the solder mask 30 and solder pads 22 when the conventional technology is utilized for forming the solder mask 30 between two solder pads 22, which means that the solder mask 30 does not cover the solder pads 22, thus a clearance d2 is formed between the solder mask 30 and the solder pads 22.

However, under the current trend of making electronic products (such as cellular phones and notebook computers) lighter and smaller, the spacings between solder pads of electronic parts on a printed circuit board are required to become smaller. When the central spacing d of solder pads is smaller than or equal to 0.5 mm, the design of the clearance d2 between the solder mask 30 and the solder pads 22 would reach the extreme limit of 50-75 μm alignment precision in the negative-film exposure process of conventional solder mask mass production, thus causing the manufacturing process to be more difficult, and the solder mask 30 might easily cover portions of the solder pads 22 due to slight inaccuracy during the negative-film exposure process (Please refer to the right portion of FIG. 5). Consequently, the solder pads 22 could not be used during the soldering process for assembling electronic parts, thus causing lower yield rates and increasing production costs. Furthermore, for assuring high yield rates, the clearance d2 between the solder mask 30 and the solder pads 22 manufactured under conventional technologies should be at least 50 g m due to the limited alignment precision of the negative-film exposure process, therefore the contact range of the solder mask 30 and the PCB 20 (Please refer to No. 21 in FIG. 6) would be too small to obtain better adhesion, with the result being that the solder mask 30 would be peeled due to high temperature during assembling processes or impact after being assembled, thus causing short circuitry and lower reliability of products.

For overcoming the foregoing drawback caused by the conventional technology, laser direct image (“LDI”) is provided to break through the limit of alignment precision in conventional negative-film exposure processes by directly printing the solder mask on overall PCB surface and exposing the dense solder pad area through laser without using the negative-film exposure technology. It is true that such LDI process is indeed capable of improving the drawback of the solder mask covering solder pads during the conventional technology, so as to assure the reliability while assembling electronic parts, and effectively minimize the clearance d2 to 25 μm for greatly improving the adhesion of the solder mask. However, the drawback for such technology is that the equipment cost goes so high that it costs over US$ 300,000.00.

### SUMMARY OF THE INVENTION

The primary object of the present invention is to provide a method for applying the solder mask onto solder pad spacings of a PCB without using the negative-film exposure technology and with lower equipment cost, which assures the reliability while assembling electronic parts, and further minimizes clearances between the solder mask and solder pads, so as to improve the adhesion of the solder mask.

The method for applying the solder mask onto solder pad spacings of a PCB to achieve the foregoing objects is to print the solder mask through an ink-jet printer to the dense solder pad area on a PCB, such that the equipment cost by using the inkjet,printer should be only one fifth of that by using the LDI technology.

Preferably, the central spacings of solder pads are smaller than or equal to 0.5 mm.

Preferably, the width of the solder mask should be no wider than 150 μm.

Preferably, the thickness of the solder mask should be no thicker than 55 μm.

Preferably, the primary material for the solder mask can be epoxy resin series, acrylic resin series or the mixture of epoxy resin series and acrylic resin series.

### BRIEF DESCRIPTION OF THE DRAWINGS

These and other features, aspects and advantages of the present invention will become better understood with regard to the following description, appended claims and accompanying drawings that are provided only for further elaboration without limiting or restricting the present invention, where:

FIG. 1 shows a flat-surface structural schematic diagram of producing the solder mask on a PCB according to the method of the present invention;

FIG. 2 shows a sectional view along the X-X line in FIG. 1;

FIG. 3 shows a diagonal alignment diagram according to the method of the present invention;

FIG. 4 shows a partial flat-surface structural diagram of a general PCB having solder pads;

FIG. 5 shows a flat-surface structural diagram of producing the solder mask on the PCB shown in FIG. 4 according to the conventional manufacturing process; and

FIG. 6 shows a sectional view along the Y-Y line in FIG. 5.

### DETAILED DESCRIPTION OF THE PREFERRED EMBODIMENT

The following is a detailed description of the best presently known modes of carrying out the inventions. This description is not to be taken in a limiting sense, but is made merely for the purpose of illustrating the general principles of the inventions.

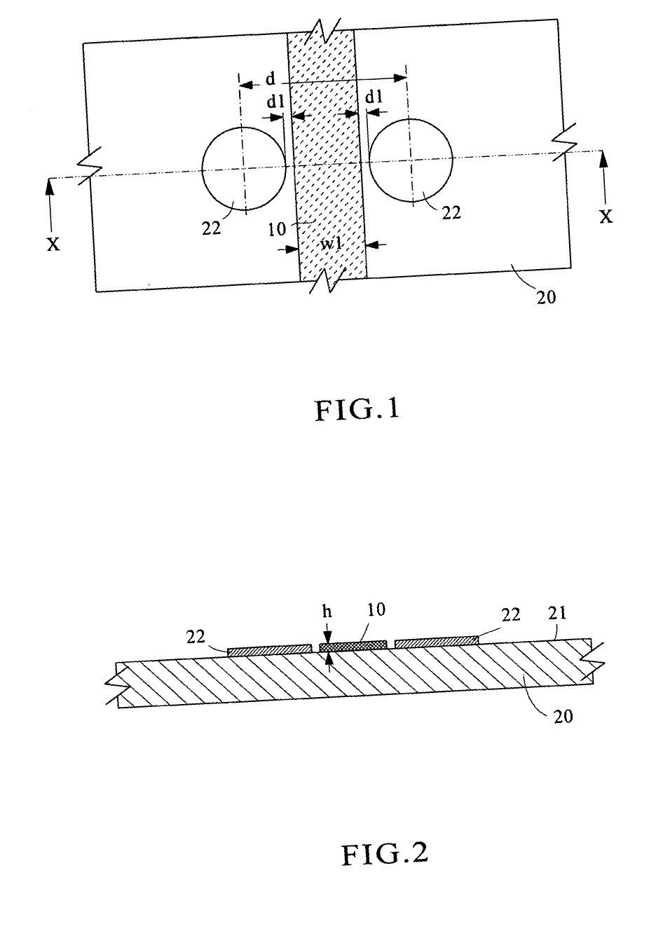

Please refer to FIG. 1 and FIG. 2, which show a plurality of solder pads 22 on the PCB surface 21.

As the central spacing d of each solder pad on the PCB 20 is larger than 0.5 mm, it is then suitable to form the solder mask according to the conventional manufacturing process. Yet as the central spacing between each solder pad 22 in certain areas on the PCB 20, such as the BGA (Ball Grid Array) area, is smaller than or equal to 0.5 mm, such BGA area is regarded as a dense solder pad area, which is to be printed with the solder mask 10 onto solder pad spacings by an ink-jet printer. Since the ink-jet printer is utilized to print the solder mask 10, the width w1 of the solder mask 10 can be no wider than 150 μm, whereas under such width, the thickness h thereof can no thicker than 55 μm.

Since the ink-jet printer is utilized to apply the solder mask 10, it is unnecessary to apply the conventional negative-film exposure technology, thus the solder mask 10 would not cover any part of the solder pads 22, therefore the reliability for assembling electronic products can be greatly improved. Further, since the clearance d1 between the solder mask 10 and the solder pads 22 can be smaller than 50 μm, which is smaller than the clearance d2 that is at least 50 μm between the conventional solder mask 30 and the solder pads 22 (See FIG. 5), thus the contact area between the solder mask 10 and the PCB surface 21 is enlarged, causing the adhesion of the solder mask to be increased, such that the solder mask 10 would not peel when encountering high temperature during assembling processes or impact after being assembled, an outcome that prevents products from short circuitry and lower product reliability.

The primary material for the solder mask 10 can be epoxy resin series, acrylic resin series or the mixture of epoxy resin series and acrylic resin series.

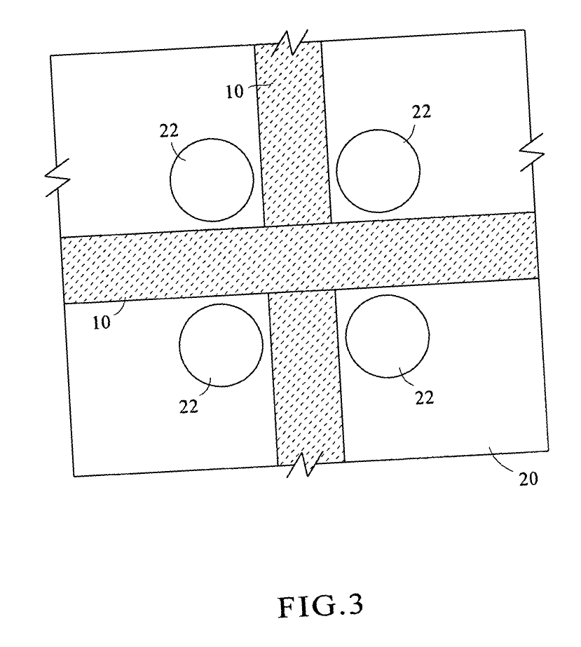

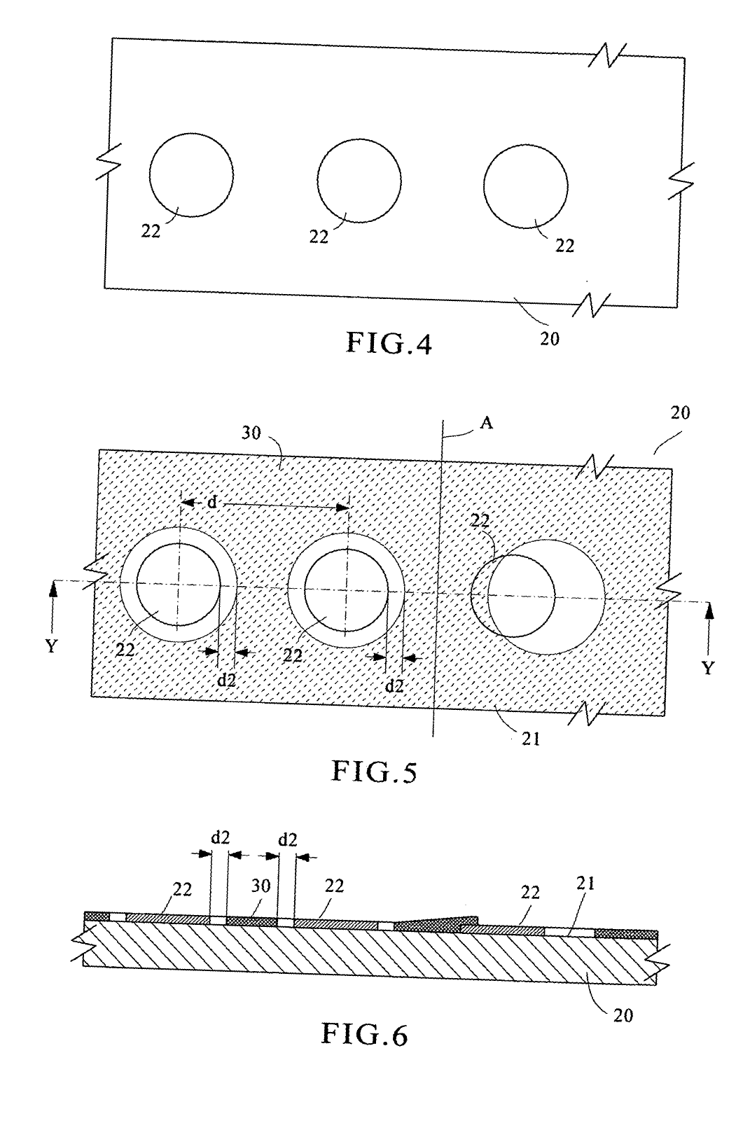

Please further refer to FIG. 3. The dense solder pad area applied with the solder mask according to the method of the present invention, such the BGA area, may include several hundred solder pads 22. FIG. 3 only shows four solder pads 22. By obtaining the alignment point on the diagonals of the PCB surface, all the solder pads 22 in the specified area, which is the dense solder pad area, shall be included in the area whereto the ink-jet printer prints the solder mask. The ink-jet printer is to vertically and horizontally print the solder mask between solder pads, so as to produce a plurality of vertical solder masks 10 and a plurality of horizontal solder masks 10, solder masks that are mutually interlaced.

Although the present invention has been described in considerable detail with reference to certain preferred embodiments thereof, those skilled in the art can easily understand that all kinds of alterations and changes can be made within the spirit and scope of the appended claims. Therefore, the spirit and scope of the appended claims should not be limited to the description of the preferred embodiments contained herein.

1. A method for applying solder mask onto solder pad spacings on a printed circuit board, characterized in that, an ink-jet printer is employed to print solder mask onto solder pad spacings on a printed circuit board.

2. The method for applying solder mask onto solder pad spacings on a printed circuit board as in claim 1, wherein the central spacings of said solder pads are smaller than or equal to 0.5 mm.

3. The method for applying solder mask onto solder pad spacings on a printed circuit board as in claim 1, wherein the width of said solder mask is no wider than 150 μm.

4. The method for applying solder mask onto solder pad spacings on a printed circuit board as in claim 1, wherein the thickness of said solder mask is no thicker than 55 μm.

5. The method for applying solder mask onto solder pad spacings on a printed circuit board as in claim 1, wherein the primary material for said solder mask can be epoxy resin series, acrylic resin series or the mixture of epoxy resin series and acrylic resin series.
